(19) United States
(12) Patent Application Publication
(10) Pub. No.: US 2025/0318358 A1
(43) Pub. Date: Oct. 9, 2025

(54) COMPOSITION FOR ENCAPSULATING ORGANIC LIGHT EMITTING DIODES AND ORGANIC LIGHT EMITTING DIODE DISPLAY

(71) Applicant: SAMSUNG SDI CO., LTD., Yongin-si (KR)

(72) Inventors: Ji Yeon LEE, Suwon-si (KR); Seong Ryong NAM, Suwon-si (KR); Jee Hyun RYU, Suwon-si (KR); Se ll OH, Suwon-si (KR); Myong Sook HAN, Suwon-si (KR)

(21) Appl. No.: 19/172,931

(22) Filed: Apr. 8, 2025

(30) Foreign Application Priority Data
Apr. 9, 2024 (KR) 10-2024-0048146

(51) Int. Cl. H10K 50/844; C08F 20/18

(52) U.S. Cl. CPC H10K 50/844; C08F 20/18

(57) ABSTRACT

A composition for encapsulation of organic light emitting diodes, the composition including a curable component including a photocurable bifunctional aliphatic monomer, a photocurable monofunctional aromatic monomer, a photocurable monofunctional aliphatic monomer, and a photocurable bifunctional aromatic monomer; and a photoinitiator, wherein the composition has an R-parameter of 0.1 to 0.17.

### CROSS-REFERENCE TO RELATED APPLICATION

The present application claims priority and the benefit of Korean Patent Application No. 10-2024-0048146, filed on Apr. 9, 2024 in the Korean Intellectual Property Office, the entire disclosure of which is incorporated herein by reference.

### 1. Field

Embodiments relate to a composition for encapsulation of organic light emitting diodes and an organic light emitting diode display.

### 2. Description of the Related Art

Permeation of moisture, oxygen, and the like into an organic light emitting diode may cause damage to the organic light emitting diode and malfunction of the organic light emitting diode, resulting in deterioration in reliability. Therefore, there may be a need to encapsulate an organic light emitting diode with an encapsulation layer including an inorganic layer and an organic layer formed of a composition for encapsulation of organic light emitting diodes.

### SUMMARY

Embodiments are directed to a composition for encapsulation of organic light emitting diodes, the composition including a curable component including a photocurable bifunctional aliphatic monomer, a photocurable monofunctional aromatic monomer, a photocurable monofunctional aliphatic monomer, and a photocurable bifunctional aromatic monomer, and a photoinitiator, wherein the composition has an R-parameter of 0.1 to 0.17.

The photocurable bifunctional aliphatic monomer, the photocurable monofunctional aromatic monomer, the photocurable monofunctional aliphatic monomer, and the photocurable bifunctional aromatic monomer may be present, in total, in an amount of 95 wt % or more in the curable component, based on a total weight of the curable component.

The photocurable bifunctional aliphatic monomer and the photocurable monofunctional aliphatic monomer may be present in a weight ratio of 30:70 to 70:30, based on a total of 100 parts by weight of the photocurable bifunctional aliphatic monomer and the photocurable monofunctional aliphatic monomer.

The photocurable monofunctional aromatic monomer and the photocurable bifunctional aromatic monomer may be present in a weight ratio of 20:80 to 90:10, based on a total of 100 parts by weight of the photocurable monofunctional aromatic monomer and the photocurable bifunctional aromatic monomer.

The photocurable bifunctional aliphatic monomer may be represented by Formula 1:

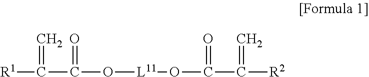

R¹ and R² may each independently be hydrogen or a C₁ to C₅ alkyl group, and L¹¹ may be a substituted or unsubstituted linear or branched C₅ to C₂₀ alkylene group.

The photocurable bifunctional aromatic monomer may be represented by Formula 4:

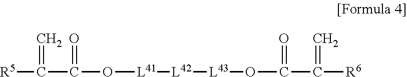

R⁵ and R⁶ may each independently be hydrogen or a C₁ to C₅ alkyl group, L⁴¹ and L⁴³ may each independently be a substituted or unsubstituted C₆ to C₂₀ arylene group, and L⁴² may be a single bond or a linear or branched C₁ to C₂₀ alkylene group.

The photocurable monofunctional aliphatic monomer may be represented by Formula 3:

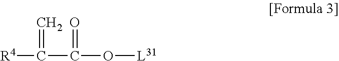

R⁴ may be hydrogen or a C₁ to C₅ alkyl group, and L³¹ may be a substituted or unsubstituted linear or branched C₈ to C₂₀ alkyl group.

The composition may include, based on a total weight of the composition 20 parts by weight to 60 parts by weight of the photocurable bifunctional aliphatic monomer, 5 parts by weight to 30 parts by weight of the photocurable monofunctional aromatic monomer, 10 parts by weight to 50 parts by weight of the photocurable monofunctional aliphatic monomer, 1 part by weight to 30 parts by weight of the photocurable bifunctional aromatic monomer, and 1 part by weight to 10 parts by weight of the photoinitiator.

Embodiments are directed to a cured film for encapsulation of organic light emitting diodes, the cured film having a permittivity of 2.8 or less and a glass transition temperature of 30° C. to 120° C.

The embodiments may be realized by providing a cured product of the composition for encapsulation of organic light emitting diodes according to an embodiment.

The embodiments may be realized by providing an organic light emitting diode display, including an organic layer including a cured product of the composition for encapsulation of organic light emitting diodes according to an embodiment.

### BRIEF DESCRIPTION OF DRAWINGS

Features will become apparent to those of skill in the art by describing in detail exemplary embodiments with reference to the attached drawings in which:

FIG. 1 is a cross-sectional view of an organic light emitting diode display according to one embodiment.

FIG. 2 is a cross-sectional view of an organic light emitting diode display according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not necessarily an exclusive term, e.g., “A or B” would include A, B, or A and B.

Herein, “(meth)acryl” refers to acryl and/or methacryl.

Herein, unless otherwise defined, “substituted” means that at least one hydrogen atom of a corresponding functional group is substituted with a halogen (F, Cl, Br, or I), a hydroxyl group, a nitro group, a cyano group, an imino group (═NH, ═NR, R being a C₁ to C₁₀ alkyl group), an amino group (—NH₂, —NH(R′), —N(R″)(R′″)′, R′, R″, and R′″ being each independently a C₁ to C₁₀ alkyl group), an amidino group, a hydrazine or hydrazone group, a carboxylic group, a C₁ to C₂₀ alkyl group, a C₆ to C₃₀ aryl group, a C₃ to C₃₀ cycloalkyl group, a C₃ to C₃₀ heteroaryl group, or a C₂ to C₃₀ heterocycloalkyl group.

Unless otherwise noted, compounds represented by chemical formulas described herein may have a structure with a hydrogen atom bonded thereto.

The terminology used herein is for the purpose of describing exemplary embodiments and is not intended to limit the present application. As used herein, the singular forms, “a”, “an”, and “the” are intended to include the plural forms as well, unless the context clearly indicates otherwise.

As used herein to represent a specific numerical range, the expression “X to Y” means “greater than or equal to X and less than or equal to Y (X≤ and ≤Y)”.

One aspect of an embodiment may relate, e.g., to a composition for encapsulation of organic light emitting diodes (hereinafter referred to as a “composition”). The composition for encapsulation of organic light emitting diodes may form an organic layer having significantly low permittivity over a broad frequency range after curing. Herein, the “organic layer” may also be referred to as a cured film for encapsulation of organic light emitting diodes.

In one embodiment, the organic layer may have significantly low permittivity over a frequency range of 100 kHz to 1,000 kHz. The organic layer may have a permittivity of 2.8 or less, e.g., 2.0 to 2.8 over a broad frequency range. Within these ranges, the organic layer may prevent the influence of external static electricity or electricity on an organic light emitting diode, thereby ensuring high performance of the organic light emitting diode.

The composition may form an organic layer having good processability and reliability. In this regard, the composition may have a glass transition temperature of, e.g., 30° C. to 120° C. or 40° C. to 120° C. after curing. Within these ranges, the composition may form an organic layer that has sufficient strength to minimize wrinkling upon deposition of an inorganic material thereon. In an implementation, the composition may have a glass transition temperature of, e.g., 40° C. to 60° C. after curing. Within these ranges, the composition may form an organic layer that has sufficient strength to minimize wrinkling upon deposition of an inorganic material thereon while having low permittivity.

The composition may provide an organic layer having a modulus of 0.8 GPa or more, e.g., 0.8 GPa to 5 GPa, after curing. Within these ranges, an organic layer formed of the composition may have sufficient strength to minimize wrinkling upon deposition of an inorganic material thereon.

The composition may have a water vapor transmission rate of 1 g/m² day or less, e.g., 0 g/m² day to 1 g/m² day, after curing. Within these ranges, an organic layer formed of the composition may improve reliability of a light emitting diode.

The composition may form a uniform organic layer due to good inkjet printability thereof. In this regard, the composition may have a viscosity of 7 cP to 100 cP, e.g. 7 cP to 60 cP, or 7 cP to 50 cP, at a temperature of 25° C.±2° C. (23° C. to 27° C.). Within these ranges, the composition may have improved inkjet printability.

The composition for encapsulation of organic light emitting diodes may include, e.g., a curable component including, e.g., a photocurable bifunctional aliphatic monomer, a photocurable monofunctional aromatic monomer, a photocurable monofunctional aliphatic monomer, or a photocurable bifunctional aromatic monomer; and a photoinitiator, wherein the composition may have an R-parameter of 0.1 to 0.17.

First, the R-parameter will be described.

In the composition including the photocurable bifunctional aliphatic monomer, the photocurable monofunctional aromatic monomer, the photocurable monofunctional aliphatic monomer, or the photocurable bifunctional aromatic monomer as the curable component, the R-parameter may be a criterion for determining whether an organic layer formed of the composition can satisfy the permittivity and glass transition temperature requirements described above. Even if the composition includes the photocurable bifunctional aliphatic monomer, the photocurable monofunctional aromatic monomer, the photocurable monofunctional aliphatic monomer, and the photocurable bifunctional aromatic monomer as the curable component, if the composition has an R-parameter outside the range of, e.g., 0.1 to 0.17, it may be difficult to ensure that an organic layer formed of the composition has a permittivity of 2.8 or less and high plasma resistance. Here, the “plasma resistance” is determined based on a plasma etch rate, which may be measured by a typical method known to those skilled in the art. In an implementation, the composition may have an R-parameter of, e.g., 0.1 to 0.165.

An R-parameter in the range of, e.g., 0.1 to 0.17 may be achieved by adjusting the type and content of each of the photocurable bifunctional aliphatic monomer, the photocurable monofunctional aromatic monomer, the photocurable monofunctional aliphatic monomer, or the photocurable bifunctional aromatic monomer.

The R-parameter of the composition may be calculated according to Equation 1.

To calculate the R-parameter, the photocurable monomers contained in the composition may be numbered from first to n^{th}. Here, n may be a natural number greater than or equal to 4. For each of the photocurable monomers, a value according to Equation 1 may be calculated, followed by summing the results to obtain the R-parameter of the composition.

$$[ ( Number of carbon atoms forming a benzene ring in a molecule of each of the first to {n}^{th} photocurable monomers \times Atomic mass of one carbon atom ) / ( Weight average molecular weight of each of the first to {n}^{th} photocurable monomers ) ] \times ( \% by weight of each of the first to {n}^{th} photocurable monomers ) . \qquad [ Equation 1 ]$$

In Equation 1, “number of carbons forming a benzene ring” may refer to the number of carbon atoms forming a benzene ring in a molecular structure of a corresponding photocurable monomer. For example, a phenyl group may have a carbon number of 6, and a naphthalene group may have a carbon number of 10. If there are two or more benzene rings in the molecular structure, the numbers of carbons forming each benzene ring may be summed.

In Equation 1, “weight average molecular weight” may be a typical Mw value known in the art, which may be obtained, e.g., based on polystyrene conversion in gel permeation chromatography (GPC).

In Equation 1, “% by weight” may be a ratio of the weight of each of the first to n^{th} photocurable monomers to the total weight of the photocurable monomers contained in the composition.

Now, each component of the composition will be described in detail.

### Curable Component

The curable component may include, e.g., a photocurable bifunctional aliphatic monomer, a photocurable monofunctional aromatic monomer, a photocurable monofunctional aliphatic monomer, or a photocurable bifunctional aromatic monomer. Herein, the curable component may refer to a photocurable component, meaning a component that can be cured by light.

According to an implementation, the photocurable bifunctional aliphatic monomer, the photocurable monofunctional aromatic monomer, the photocurable monofunctional aliphatic monomer, or the photocurable bifunctional aromatic monomer may be present, in total, in an amount of 95 wt % or more, e.g., 99 wt % to 100 wt %, in the curable component, based on a total weight of the curable component. Within these ranges, the composition may provide the desired effects described above without including unnecessary monomers.

The photocurable bifunctional aliphatic monomer or the photocurable monofunctional aliphatic monomer may be present, in total, in an amount of 50 parts by weight to 90 parts by weight, e.g., 55 parts by weight to 80 parts by weight, based on 100 parts by weight of the composition. Within these ranges, an organic layer formed of the composition may have low permittivity.

The photocurable monofunctional aromatic monomer or the photocurable bifunctional aromatic monomer may be present, in total, in an amount of 10 parts by weight to 50 parts by weight, e.g., 20 parts by weight to 45 parts by weight, based on 100 parts by weight of the composition. Within these ranges, an organic layer formed of the composition may have improved processability and reliability.

### Photocurable Bifunctional Aliphatic Monomer

The photocurable bifunctional aliphatic monomer may aid in reducing permittivity of an organic layer formed of the composition.

The photocurable bifunctional aliphatic monomer may be represented by Formula 1.

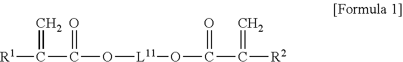

In Formula 1, R¹ and R² may each independently be or include, e.g., hydrogen or a C₁ to C₅ alkyl group. L¹¹ may be or include, e.g., a substituted or unsubstituted linear or branched C₅ to C₂₀ alkylene group.

In Formula 1, “carbon number” may refer to the number of carbon atoms in a main chain, excluding carbon atoms in a side chain. In an implementation, in Formula 1, L¹¹ may be, e.g., a substituted or unsubstituted linear or branched C₁₀ to C₁₆ or C₁₂ to C₁₄ alkylene group. In an implementation, L¹¹ may be, e.g., an unsubstituted linear C₁₀ to C₁₆ or C₁₂ to C₁₄ alkylene group.

In an implementation, L¹¹ may be, e.g., —(CH₂)₁₀—, —(CH₂)₁₁—, —(CH₂)₁₂—, —(CH₂)₁₃—, —(CH₂)₁₄—, —(CH₂)₁₅—, —(CH₂)₁₆—, —(CH₂)₁₇—, —(CH₂)₁₈—, —(CH₂)₁₉—, or —(CH₂)₂₀—. In an implementation, the monomer represented by Formula 1 may include, e.g., 1,8-octanediol di(meth)acrylate, 1,9-nonanediol di(meth)acrylate, 1,10-decanediol di(meth)acrylate, 1,11-undecanediol di(meth)acrylate, 1,12-dodecanediol di(meth)acrylate, or 1,14-tetradecanediol di(meth)acrylate.

The photocurable bifunctional aliphatic monomer may be present in an amount of 20 parts by weight to 60 parts by weight, e.g., 30 parts by weight to 50 parts by weight, based on 100 parts by weight of the composition. Within the above ranges, an organic layer formed of the composition may have low permittivity without deterioration in processability and reliability.

### Photocurable Monofunctional Aromatic Monomer

The photocurable monofunctional aromatic monomer may improve reliability and processability of an organic layer formed of the composition. The photocurable bifunctional aliphatic monomer and the photocurable monofunctional aliphatic monomer alone may not ensure high reliability and processability of an organic layer formed of the composition, despite being effective at reducing permittivity of the organic layer. In this regard, the photocurable monofunctional aromatic monomer may help improve processability and reliability of the organic layer through adjustment of the modulus and glass transition temperature of the organic layer.

The photocurable monofunctional aromatic monomer may be represented by Formula 2.

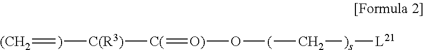

In Formula 2, R³ may be or include, e.g., hydrogen or a C₁ to C₅ alkyl group, s may be, e.g., an integer of 0 to 10, and L²¹ may be or include, e.g., a substituted or unsubstituted C₆ to C₅₀ aryl group or a substituted or unsubstituted C₆ to C₅₀ aryloxy group.

In an implementation, L²¹ may be, e.g., a phenylphenoxyethyl group, a phenoxyethyl group, a benzyl group, a phenyl group, a phenylphenoxy group, a phenoxy group, a phenylethyl group, a phenylpropyl group, a phenylbutyl group, a methylphenylethyl group, a propylphenylethyl group, a methoxyphenylethyl group, a cyclohexylphenylethyl group, a chlorophenylethyl group, a bromophenylethyl group, a methylphenyl group, a methylethylphenyl group, a methoxyphenyl group, a propylphenyl group, a cyclohexylphenyl group, a chlorophenyl group, a bromophenyl group, a phenylphenyl group, a biphenyl group, a terphenyl group, a quaterphenyl group, an anthracenyl group, a naphthalenyl group, a triphenylenyl group, a methylphenoxy group, an ethylphenoxy group, a methylethylphenoxy group, a methoxyphenyloxy group, a propylphenoxy group, a cyclohexylphenoxy group, a chlorophenoxy group, a bromophenoxy group, a biphenyloxy group, a terphenyloxy group, a quaterphenyloxy group, an anthracenyloxy group, a naphthalenyloxy group, or a triphenylenyloxy group.

In an implementation, the photocurable monofunctional aromatic monomer may include, e.g., 2-phenylphenoxyethyl (meth)acrylate, naphthyl (meth)acrylate, naphthalenylmethyl (meth)acrylate, phenoxyethyl (meth)acrylate, phenyl (meth)acrylate, phenoxy (meth)acrylate, 2-ethylphenoxy (meth)acrylate, benzyl (meth)acrylate, 2-phenylethyl (meth)acrylate, 3-phenylpropyl (meth)acrylate, 4-phenylbutyl (meth)acrylate, 2-(2-methylphenyl)ethyl (meth)acrylate, 2-(3-methylphenyl)ethyl (meth)acrylate, 2-(4-methylphenyl)ethyl (meth)acrylate, 2-(4-propylphenyl)ethyl (meth)acrylate, 2-(4-(1-methylethyl)phenyl)ethyl (meth)acrylate, 2-(4-methoxyphenyl)ethyl (meth)acrylate, 2-(4-cyclohexylphenyl)ethyl (meth)acrylate, 2-(2-chlorophenyl)ethyl (meth)acrylate, 2-(3-chlorophenyl)ethyl (meth)acrylate, 2-(4-chlorophenyl)ethyl (meth)acrylate, 2-(4-bromophenyl)ethyl (meth)acrylate, 2-(3-phenylphenyl)ethyl (meth)acrylate, 4-(biphenyl-2-yloxy)butyl (meth)acrylate, 3-(biphenyl-2-yloxy)butyl (meth)acrylate, 2-(biphenyl-2-yloxy)butyl (meth)acrylate, 1-(biphenyl-2-yloxy)butyl (meth)acrylate, 4-(biphenyl-2-yloxy) propyl (meth)acrylate, 3-(biphenyl-2-yloxy) propyl (meth)acrylate, 2-(biphenyl-2-yloxy) propyl (meth)acrylate, 1-(biphenyl-2-yloxy) propyl (meth)acrylate, 4-(biphenyl-2-yloxy)ethyl (meth)acrylate, 3-(biphenyl-2-yloxy)ethyl (meth)acrylate, 2-(biphenyl-2-yloxy)ethyl (meth)acrylate, 1-(biphenyl-2-yloxy)ethyl (meth)acrylate, 2-(4-benzylphenyl)ethyl (meth)acrylate, 1-(4-benzylphenyl)ethyl (meth)acrylate, or a structural isomer thereof. The (meth)acrylates described herein are exemplary and the photocurable monofunctional aromatic monomer according to the present embodiments may include any structural isomers of the aforementioned (meth)acrylates. For example, 2-phenylethyl (meth)acrylate is described as an example of the photocurable monofunctional aromatic monomer and it may it be understood that the photocurable monofunctional aromatic monomer may include any isomer of 2-phenylethyl (meth)acrylate, e.g., 3-phenylethyl (meth)acrylate, 4-phenyl (meth)acrylate, or the like.

In an implementation, the photocurable monofunctional aromatic monomer may be, e.g., a monomer represented by Formula 2 wherein L²¹ is a phenylphenoxyethyl group or a biphenylyl group.

The photocurable monofunctional aromatic monomer may be present in an amount of 5 parts by weight to 30 parts by weight, e.g., 10 parts by weight to 30 parts by weight, based on 100 parts by weight of the composition. Within these ranges, the photocurable monofunctional aromatic monomer may reduce permittivity of an organic layer formed of the composition while improving reliability and processability of the organic layer.

### Photocurable Monofunctional Aliphatic Monomer

The composition may further include, e.g., the photocurable monofunctional aliphatic monomer as the photocurable aliphatic monomer, in addition to the photocurable bifunctional aliphatic monomer.

Both the photocurable bifunctional aliphatic monomer and the photocurable monofunctional aliphatic monomer may reduce permittivity of an organic layer formed of the composition. However, a composition including only the photocurable bifunctional aliphatic monomer without the photocurable monofunctional aliphatic monomer may have less ability to reduce permittivity of the organic layer. In addition, a composition including only the photocurable monofunctional aliphatic monomer without the photocurable bifunctional aliphatic monomer may not cure as well as a composition including both the photocurable bifunctional aliphatic monomer and the photocurable monofunctional aliphatic monomer. Thus, the resulting formation of the organic layer may be affected.

In this regard, the photocurable bifunctional aliphatic monomer and the photocurable monofunctional aliphatic monomer may be present in a weight ratio of 30:70 to 70:30, e.g., 40:60 to 70:30, based on a total of 100 parts by weight of the photocurable bifunctional aliphatic monomer and the photocurable monofunctional aliphatic monomer. Within these ranges, the composition may have high UV curing conversion while ensuring reduction in permittivity of an organic layer formed of the composition.

The photocurable monofunctional aliphatic monomer may be represented by Formula 3.

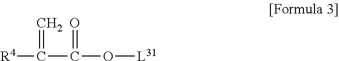

In Formula 3, R⁴ may be or include, e.g., hydrogen or a C₁ to C₅ alkyl group, and L³¹ may be, e.g., a substituted or unsubstituted linear or branched C₅ to C₂₀ alkyl group.

In Formula 3, “carbon number” may refer to the number of carbon atoms in a main chain, excluding carbon atoms in a side chain.

In an implementation, in Formula 3, L³¹ may be, e.g., a substituted or unsubstituted linear or branched C₁₀ to C₂₀ or C₁₀ to C₁₈ alkyl group.

In an implementation, in Formula 3, L³¹ may be, e.g., a substituted linear C₁₀ to C₂₀ or C₁₀ to C₁₈ alkyl group.

In an implementation, the monomer represented by Formula 3 may include, e.g., octyl (meth)acrylate, nonyl (meth)acrylate, decyl (meth)acrylate, tetradecyl (meth)acrylate including, e.g., 2-decyl 1-tetradecanyl (meth)acrylate or the like, undecyl (meth)acrylate, dodecyl (meth)acrylate, stearyl (meth)acrylate, isostearyl (meth)acrylate, or cetyl (meth)acrylate. In an implementation, the monomer represented by Formula 3 may include, e.g., stearyl (meth)acrylate or 2-decyl-1-tetradecanyl (meth)acrylate.

The photocurable monofunctional aliphatic monomer may be present in an amount of 10 parts by weight to 50 parts by weight, e.g., 20 parts by weight to 40 parts by weight, based on 100 parts by weight of the composition. Within these ranges, the photocurable monofunctional aliphatic monomer may help reduce permittivity of an organic layer formed of the composition while helping improve reliability and processability of the organic layer.

### Photocurable Bifunctional Aromatic Monomer

The composition may further include the photocurable bifunctional aromatic monomer as the photocurable aromatic monomer, in addition to the photocurable monofunctional aromatic monomer.

Both the photocurable monofunctional aromatic monomer and the photocurable bifunctional aromatic monomer may help improve processability and reliability of an organic layer formed of the composition. However, a composition including only the photocurable bifunctional aromatic monomer without the photocurable monofunctional aromatic monomer may have less ability to reduce permittivity of the organic layer. In addition, a composition including only the photocurable monofunctional aromatic monomer without the photocurable bifunctional aromatic monomer may not cure as well as a composition including both the photocurable monofunctional aromatic monomer and the photocurable bifunctional aromatic monomer. Thus, the resulting formation of the organic layer may be affected.

In this regard, the photocurable monofunctional aromatic monomer and the photocurable bifunctional aromatic monomer may be present in a weight ratio of 20:80 to 90:10, e.g., 30:70 to 90:10, based on a total of 100 parts by weight of the photocurable monofunctional aromatic monomer and the photocurable bifunctional aromatic monomer. Within these ranges, the composition may have a high UV curing conversion while helping ensure reduction in permittivity of an organic layer formed of the composition.

The photocurable bifunctional aromatic monomer may be represented by Formula 4.

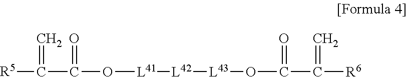

In Formula 4, R⁵ and R⁶ may each independently be or include, e.g., hydrogen or a C₁ to C₅ alkyl group. L⁴¹ and L⁴³ may each independently be or include, e.g., a substituted or unsubstituted C₆ to C₂₀ arylene group. L⁴² may be or include, e.g., a single bond or a linear or branched C₁ to C₂₀ alkylene group.

In an implementation, in Formula 4, L⁴² may be, e.g., a single bond or a linear or branched C₁ to C₁₀ alkylene group. In an implementation, L⁴² may be a substituted or unsubstituted linear or branched C₁ to C₅ alkylene group.

In an implementation, the monomer represented by Formula 4 may include, e.g., bisphenol A di(meth)acrylate or phenol,4,4-methylenedi-,dimethacrylate (bisphenol F dimethacrylate).

The photocurable bifunctional aromatic monomer may be present in an amount of 1 part by weight to 30 parts by weight, e.g., 1 part by weight to 20 parts by weight, based on 100 parts by weight of the composition. Within these ranges, the photocurable bifunctional aromatic monomer may help reduce permittivity of an organic layer formed of the composition while helping improve reliability and processability of the organic layer.

### Photoinitiator

The photoinitiator may include any typical photopolymerization initiator that can initiate photocuring reaction. In an implementation, the photopolymerization initiator may include, e.g., a triazine initiator, an acetophenone initiator, a benzophenone initiator, a thioxanthone initiator, a benzoin initiator, a phosphorus initiator, an oxime initiator, or a mixture thereof.

In an implementation, the photoinitiator may include a phosphorus initiator having a maximum absorption wavelength of 360 nm to 400 nm. The phosphorus initiator may be more effective at initiating the photocuring reaction of the composition according an embodiment under long-wavelength UV light (e.g., 300 nm to 400 nm). The phosphorus initiator may include diphenyl, e.g., (2,4,6-trimethylbenzoyl) phosphine oxide, phenyl bis(2,4,6-trimethylbenzoyl) phosphine oxide, 2,4,6-trimethylbenzoyl diphenylphosphinate, or a mixture thereof. In an implementation, these initiators may be used alone or as a mixture thereof. The “maximum absorption wavelength” may be measured by a suitable method or may be obtained from product catalogs.

The photoinitiator may be present in an amount of 1 part by weight to 10 parts by weight, e.g., 1 part by weight to 5 parts by weight, based on 100 parts by weight of the composition. Within these ranges, the photoinitiator may help enhance UV curing conversion of the composition without causing reduction in light transmittance of an organic layer due to a residue of the photoinitiator.

The composition may be prepared by mixing the curable component with the photoinitiator. In an implementation, the composition according to an embodiment may be of a solvent-free type that does not contain any solvent.

The composition may be, e.g., a photocurable composition and may be cured into an encapsulation layer through UV irradiation at a fluence of, e.g., 10 mW/cm² to 500 mW/cm² for 1 to 50 seconds.

The composition may further include suitable additives. The additives may include, e.g., a heat stabilizer, an antioxidant, a UV absorber, or the like.

The composition may have a viscosity of 7 cP to 100 cP, e.g., 7 cP to 60 cP or 7 cP to 50 cP, at a temperature of 25° C.±2° C. (23° C. to 27° C.). Within these ranges, the composition may have good inkjet printability.

The composition may have a UV curing conversion of 89% to 100%, e.g., 91% to 99% or 91% to 93%. Within these ranges, a cured product of the composition may function as an organic layer. The “UV curing conversion” may be measured as follows.

First, with respect to the composition for encapsulation, intensities of absorption peaks near 1,635 cm⁻¹ (C═C) and 1,720 cm⁻¹ (C═O) may be measured using an FT-IR spectrometer (NICOLET 4700, Thermo Electronics). Thereafter, the composition may be applied to a glass substrate by spraying, followed by curing through irradiation with UV light (wavelength: 395 nm) at a fluence of 4,000 mJ/cm² under an oxygen concentration of 5 ppm or less, thereby obtaining a specimen having a size of 20 cm×20 cm×3 μm (width×length×thickness). Thereafter, the cured film may be divided into aliquots, followed by measurement of intensities of absorption peaks near 1,635 cm⁻¹ (C═C) and 1,720 cm⁻¹ (C═O) using an FT-IR spectrometer (NICOLET 4700, Thermo Electronics). The UV curing conversion may be calculated according to Equation 2.

$$UV curing conversion ( \% ) = \vert 1 - ( A / B ) \vert \times 100$$

In Equation 2, A may be an intensity ratio of an absorption peak near 1,635 cm⁻¹ to an absorption peak near 1,720 cm⁻¹, as measured with respect to the cured film, and B may be an intensity ratio of an absorption peak near 1,635 cm⁻¹ to an absorption peak near 1,720 cm⁻¹, as measured with respect to the composition for encapsulation.

The composition may be used, e.g., to encapsulate an organic light emitting diode. In an implementation, the composition may form an organic layer in an encapsulation structure in which an inorganic layer and an organic layer are sequentially formed.

The composition may also be used to encapsulate a member for apparatuses, e.g., a member for display apparatuses that would otherwise suffer degradation or malfunction due to permeation of surrounding gases or liquids, e.g., atmospheric oxygen and/or moisture and/or water vapor, and permeation of chemicals used in processing into electronics. In an implementation, the member for apparatuses may include, e.g., luminaires, metal sensor pads, microdisc lasers, electrochromic devices, photochromic devices, microelectromechanical systems, solar cells, integrated circuits, charge coupled devices, or light emitting polymers.

Another aspect of some of the present embodiments relates to a cured film for encapsulation of organic light emitting diodes.

The cured film for encapsulation of organic light emitting diodes may have a permittivity of 2.8 or less and a glass transition temperature of 30° C. to 120° C. Since these characteristics have been described above, detailed description thereof will be omitted.

The cured film may include, e.g., a cured product of the composition for encapsulation of organic light emitting diodes described above.

A further aspect of the present application may relate to, e.g., an organic light emitting diode display.

The organic light emitting diode display may include, e.g., an organic layer including the composition for encapsulation of organic light emitting diodes according to an embodiment. In an implementation, the organic light emitting diode display may include, e.g., an organic light emitting diode and a barrier stack on the organic light emitting diode and including an inorganic layer and an organic layer, wherein the organic layer may include of the composition for encapsulation of organic light emitting diodes according to an embodiment. Thus, the organic light emitting diode display may have high reliability.

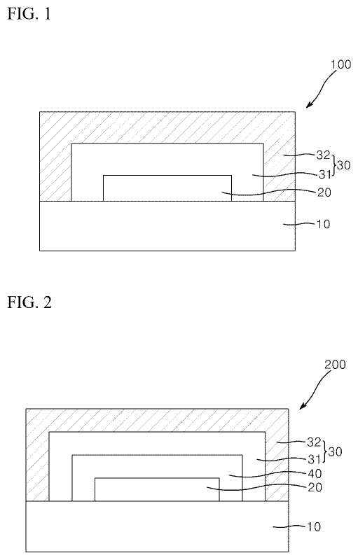

An organic light emitting diode display according to one embodiment will be described with reference to FIG. 1. FIG. 1 is a cross-sectional view of an organic light emitting diode display according to one embodiment.

Referring to FIG. 1, the organic light emitting diode display 100 according to this embodiment may include, e.g., a substrate 10, an organic light emitting diode 20 on the substrate 10, and a barrier stack 30 on the organic light emitting diode 20 and including, e.g., an inorganic layer 31 and an organic layer 32, wherein the inorganic layer 31 may adjoin the organic light emitting diode 20, and the organic layer 32 may include the composition for encapsulation of organic light emitting diodes according to an embodiment.

As the substrate 10, any suitable substrate may be used so long as the organic light emitting diode can be formed on the substrate. In an implementation, the substrate 10 may be, e.g., a transparent glass substrate, a plastic sheet substrate, a silicon substrate, a metal substrate, or the like.

The organic light emitting diode 20 may include, e.g., any suitable organic light emitting diode for use in an organic light emitting diode display. The organic light emitting diode 20 may include, e.g., a first electrode, a second electrode, and an organic light emitting film between the first electrode and the second electrode. Here, the organic light emitting film may have a structure in which a hole injection layer, a hole transport layer, a light emitting layer, an electron transport layer, and an electron injection layer may be sequentially stacked.

The barrier stack 30 may include, e.g., the organic layer and the inorganic layer, wherein the organic layer and the inorganic layer may be formed of different materials to perform respective functions thereof with regard to encapsulation of the organic light emitting diode.

The inorganic layer may include a different material than the organic layer to supplement the effects of the organic layer. In an implementation, the inorganic layer may include, e.g., a metal; a nonmetal; a compound or alloy of at least two metals; a compound or alloy of at least two nonmetals; an oxide of a metal or a nonmetal; a fluoride of a metal or a nonmetal; a nitride of a metal or a nonmetal; a carbide of a metal or a nonmetal; an oxynitride of a metal or a nonmetal; a boride of a metal or a nonmetal; an oxyboride of a metal or a nonmetal; a silicide of a metal or a nonmetal; or a mixture thereof. The metal or the nonmetal may include, e.g., silicon (Si), aluminum (Al), selenium (Se), zinc (Zn), antimony (Sb), indium (In), germanium (Ge), tin (Sn), bismuth (Bi), a transition metal, and a lanthanide metal. In an implementation, the inorganic layer may include, e.g., silicon oxide (SiOₓ), silicon nitride (SiNₓ), silicon oxynitride (SiOₓN_{y}), zinc selenide (ZnSe), zinc oxide (ZnO), antimony trioxide (Sb₂O₃), aluminum oxide (AlOₓ) including alumina (Al₂O₃) or the like, indium oxide (In₂O₃), or tin oxide (SnO₂).

The inorganic layer may be deposited by a plasma process or a vacuum process, e.g., sputtering, chemical vapor deposition, plasma chemical vapor deposition, evaporation, sublimation, electron cyclotron resonance plasma-enhanced chemical vapor deposition, or a combination thereof.

The organic layer may be alternately deposited with the inorganic layer to secure smoothing properties of the inorganic layer and to prevent defects of one inorganic layer from spreading to other inorganic layers.

The organic layer may be formed by a combination of coating, deposition, and curing of the composition for encapsulation of organic light emitting diodes according to an embodiment. In an implementation, the organic layer may be formed by coating the composition to a thickness of, e.g., about 1 μm to about 50 μm, followed by curing the composition through UV irradiation at a fluence of, e.g., 10 mW/cm² to 500 mW/cm² for 1 to 50 seconds.

The barrier stack may include a suitable number of organic and inorganic layers. The total number of organic and inorganic layers may be varied depending on the desired level of permeation resistance to oxygen and/or moisture and/or water vapor and/or chemicals. In an implementation, the organic and inorganic layers may be formed in a total of 10 layers or less, e.g., 2 to 7 layers. In an implementation, the organic and inorganic layers may be formed in a total of 7 layers in the following order: inorganic layer/organic layer/inorganic layer/organic layer/inorganic layer/organic layer/inorganic layer.

In the barrier stack, the organic and inorganic barrier layers may be alternately deposited. This structure may help ensure that the organic layer formed of the composition provides the desired effects described above. In this way, the organic layer and the inorganic layer may supplement or reinforce each other with regard to encapsulation of the member for apparatuses.

An organic light emitting diode display according to another embodiment will be described with reference to FIG. 2. FIG. 2 is a cross-sectional view of an organic light emitting diode display according to another embodiment.

Referring to FIG. 2, the organic light emitting diode display 200 according to this embodiment may include, e.g., a substrate 10, an organic light emitting diode 20 on the substrate 10, and a barrier stack 30 on the organic light emitting diode 20 and including, e.g., an inorganic layer 31 and an organic layer 32, wherein the inorganic layer 31 may encapsulate an inner space 40 receiving the organic light emitting diode 20 therein, and the organic layer 32 may include the composition for encapsulation of organic light emitting diodes according to an embodiment. The organic light emitting diode display 200 according to this embodiment may be substantially the same as the organic light emitting diode display according to the above embodiment except that the inorganic layer may not adjoin the organic light emitting diode.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Details of components used in Examples and Comparative Examples were as follows:
(A) Photocurable bifunctional aliphatic monomer
(A1) 1,12-dodecanediol dimethacrylate (Sartomer Co., Inc.)
(A2) 1,14-tetradecanediol dimethacrylate (Miwon Chemical Co., Ltd.)
(A3) Triethylene glycol dimethacrylate (Aldrich Chemical Co., Inc.)
(B) Photocurable monofunctional aromatic monomer
(B1) O-phenylphenoxyethyl acrylate (Green Chemicals Co., Ltd.)
(B2) 4-biphenylyl methacrylate (Green Chemicals Co., Ltd.)
(B3) 2-phenyl-2-(phenylthio)ethyl 2-propenoate (represented by formula below, prepared using benzene thiol, zinc perchlorate, styrene oxide, and acryloyl chloride)

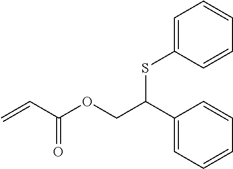 [SMILES: C=CC(=O)OCC(Sc1ccccc1)c1ccccc1]

(C) Photocurable monofunctional aliphatic monomer
(C1) Stearyl methacrylate (Green Chemicals Co., Ltd.)
(C2) 2-decyl-1-tetradecanyl methacrylate (Kyoeisha Chemical Co., Ltd.)
(C3) 2-(dimethylamino)ethyl acrylate (Aldrich Chemical Co., Inc.)
(D) Photocurable bifunctional aromatic monomer
(D1) Bisphenol A dimethacrylate (Tokyo Chemical Industry Co., Ltd.)
(D2) Phenol,4,4-methylenedi-,dimethacrylate (represented by formula below, Chemieliva Pharmaceutical Co., Ltd.)

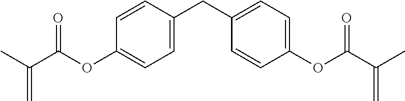 [SMILES: C=C(C)C(=O)Oc1ccc(Cc2ccc(OC(=O)C(=C)C)cc2)cc1]

(D3) 1,1′-[[1,1′-biphenyl]-2,2′-diylbis(oxy-2,1-ethanediyl)] di-2-propenoate (represented by formula below, prepared using 2-hydroxyethyl acrylate and p-toluenesulfonyl chloride)

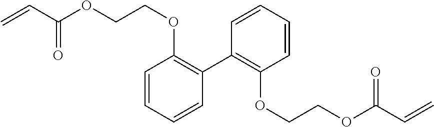 [SMILES: C=CC(=O)OCCOc1ccccc1-c1ccccc1OCCOC(=O)C=C]

(E) Photoinitiator (phosphorus initiator, Darocur TPO, BASF Co., Ltd.)

### Example 1

50 parts by weight of (A2), 20 parts by weight of (B2), 24 parts by weight of (C2), 3 parts by weight of (D1), and 3 parts by weight of (E) were placed in a 125 ml brown polypropylene bottle, followed by mixing with a shaker at ambient temperature for 3 hours, thereby preparing a composition for encapsulation.

### Examples 2 to 4 and Comparative Examples 1 to 6

Compositions for encapsulation were prepared in the same manner as in Example 1 except that the content of each component were changed as listed in Table 1 (unit: parts by weight). In Table 1, “-” means that a corresponding component was not used.

Each of the compositions prepared in Examples 1 to 4 and Comparative Examples 1 to 6 was evaluated as to the following properties. Results are shown in Table 1.

(1) Permittivity: Each of the compositions prepared in Examples 1 to 4 and Comparative Examples 1 to 6 was coated to a predetermined thickness onto a chromium (Cr) plate, followed by curing through UV irradiation (wavelength: 395 nm) at a fluence of 4,000 mW/cm² under an oxygen concentration of 5 ppm or less, thereby forming an 8 μm thick coating film. Aluminum (an electrode for permittivity measurement) was deposited on the coating film, followed by measurement of permittivity of the coating film using an impedance analyzer (E4990A) at 200 kHz and 25° C.

(2) Modulus of organic layer (unit: GPa): Each of the compositions prepared in Examples 1 to 4 and Comparative Examples 1 to 6 was coated to a predetermined thickness onto a glass plate, followed by curing through UV irradiation (wavelength: 395 nm) at a fluence of 4,000 mW/cm² under an oxygen concentration of 5 ppm or less to form an 8 μm thick organic layer, thereby preparing a specimen for modulus measurement. The modulus of the specimen was measured using a nanoindenter G200 (Agilent Technologies Inc.). Here, measurement of the modulus was carried out by loading the specimen onto the nanoindenter for 5 seconds, holding the specimen for 2 seconds, and unloading the specimen for 5 seconds under conditions of temperature: 25° C., experimental mode: indentation mode (using a Berkovitz tip), control mode: force control, and maximum force: 60 μN (0213-TJ: 54 μN at a displacement of 100 nm).

(3) Glass transition temperature (Tg) of organic layer (unit: ° C.): Each of the compositions prepared in Examples 1 to 4 and Comparative Examples 1 to 6 was coated to a predetermined thickness onto a silicon wafer, followed by curing through UV irradiation (wavelength: 395 nm) at a fluence of 4,000 mW/cm² under an oxygen concentration of 5 ppm or less, thereby forming a cured coating film as an organic layer. The cured coating film was removed from the silicon wafer, followed by measurement of the glass transition temperature of the cured coating film using a differential scanning calorimeter (TA instruments).

(4) Water vapor transmission rate (WVTR) (unit: g/m²·day): Each of the compositions prepared in Examples 1 to 4 and Comparative Examples 1 to 6 was coated to a predetermined thickness onto an 80 μm thick water-permeable PET film as a substrate, followed by curing through UV irradiation (wavelength: 395 nm) at a fluence of 4,000 mW/cm² under an oxygen concentration of 5 ppm or less, thereby forming an 8 μm thick organic layer. Thereafter, a 0.1 μm thick SiNₓ layer was deposited over the organic layer by PECVD under conditions of SiH₄: 30 sccm, N₂: 800 sccm, plasma power: 150 W, and substrate temperature: 100° C., followed by measurement of WVTR using a permeation analyzer (permatran-W 700, Mocon Inc.) under conditions of RH: 100%, pressure: 760 mmHg, carrier gas: nitrogen at 0% RH until saturation point.

(5) R-parameter: A value according to Equation 1 was calculated for each photocurable monomer in each of the compositions prepared in Examples 1 to 4 and Comparative Examples 1 to 6, followed by summing the results to obtain an R-parameter.

TABLE 1

| | | Examples | | | | Comparative Examples | | | | | |
|---|---|---|---|---|---|---|---|---|---|---|---|
| | | 1 | 2 | 3 | 4 | 1 | 2 | 3 | 4 | 5 | 6 |
| A | A1 | — | 40 | — | 30 | 60 | 35 | 65 | — | — | — |
| | A2 | 50 | — | 50 | — | — | — | — | 50 | — | — |
| | A3 | — | — | — | — | — | — | — | — | — | 29 |
| B | B1 | — | 12 | — | — | — | — | — | — | 27 | — |
| | B2 | 20 | — | 17 | 12 | — | 30 | — | 32 | — | — |
| | B3 | — | — | — | — | — | — | — | — | — | 19 |
| C | C1 | — | 30 | — | 35 | — | 32 | — | — | — | — |
| | C2 | 24 | — | 25 | — | 22 | — | 32 | — | 50 | — |
| | C3 | — | — | — | — | — | | — | — | — | 30 |
| D | D1 | 3 | 15 | — | — | 15 | — | — | 15 | — | — |
| | D2 | — | — | 5 | 20 | — | — | — | — | 20 | — |
| | D3 | — | — | — | — | — | — | — | — | — | 19 |

| | | | | | | | | | | |
|---|---|---|---|---|---|---|---|---|---|---|
| E | 3 | 3 | 3 | 3 | 3 | 3 | 3 | 3 | 3 | 3 |
| Total | 100 | 100 | 100 | 100 | 100 | 100 | 100 | 100 | 100 | 100 |
| Permittivity | 2.78 | 2.64 | 2.72 | 2.68 | 3.17 | 2.93 | 2.76 | 4.21 | NG | 5.17 |
| Modulus | 1.26 | 1.38 | 1.28 | 1.27 | 0.63 | 0.52 | 0.04 | 2.1 | NG | 3.4 |
| Glass | 42 | 54 | 39 | 52 | 18 | 7.5 | −40 | 86 | NG | 91 |
| transition | | | | | | | | | | |
| temperature | | | | | | | | | | |
| WVTR | 0.3 | 0.4 | 0.5 | 0.4 | 8.9 | 8.5 | 9.2 | 0.5 | NG | 0.9 |
| R-parameter | 0.1368 | 0.1279 | 0.1279 | 0.163 | 0.0611 | 0.1868 | 0 | 0.2604 | 0.2386 | 0.1729 |

NG: Measurement is not possible because the cured layer has not been formed.

As can be seen from Table 1, the composition for encapsulation of organic light emitting diodes according to some of the present embodiments, including (A), (B), (C), and (D) in amounts in the ranges set forth herein was confirmed to be effective as an encapsulation material since the compositions had R-parameters of 0.1 to 0.17 and thus exhibited low permittivity without reduction in glass transition temperature and modulus thereof, thereby ensuring that an organic layer formed thereof had a low water vapor transmission rate.

By way of summation and review, an encapsulation layer may have a structure in which an organic layer and an inorganic layer are alternately formed. In an implementation, an encapsulation layer may be formed by alternately forming an organic layer and an inorganic layer on an organic light emitting diode in a sequence of organic layer/inorganic layer/organic layer/inorganic layer. Unlike the organic layer, the inorganic layer may be formed of an inorganic material. Generally, the inorganic layer may be formed by a plasma process or a vacuum process, such as sputtering, chemical vapor deposition, plasma chemical vapor deposition, evaporation, sublimation, electron cyclotron resonance plasma-enhanced chemical vapor deposition, or a combination thereof.

Embodiments of the present disclosure may provide a composition for encapsulation of organic light emitting diodes that can form an organic layer having low permittivity.

Embodiments of the present disclosure may provide a composition for encapsulation of organic light emitting diodes that may form an organic layer having good processability and reliability by minimizing wrinkling upon repeated deposition of an inorganic layer over the organic layer.

Embodiments of the present disclosure may provide a composition for encapsulation of organic light emitting diodes that may have good inkjet printability.

Embodiments of the present disclosure may provide a composition for encapsulation of organic light emitting diodes.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A composition for encapsulation of organic light emitting diodes, the composition comprising:
a curable component including a photocurable bifunctional aliphatic monomer, a photocurable monofunctional aromatic monomer, a photocurable monofunctional aliphatic monomer, and a photocurable bifunctional aromatic monomer; and
a photoinitiator,
wherein the composition has an R-parameter of 0.1 to 0.17.

2. The composition as claimed in claim 1, wherein the photocurable bifunctional aliphatic monomer, the photocurable monofunctional aromatic monomer, the photocurable monofunctional aliphatic monomer, and the photocurable bifunctional aromatic monomer are present, in total, in an amount of 95 wt % or more in the curable component, based on a total weight of the curable component.

3. The composition as claimed in claim 1, wherein the photocurable bifunctional aliphatic monomer and the photocurable monofunctional aliphatic monomer are present in a weight ratio of 30:70 to 70:30, based on a total of 100 parts by weight of the photocurable bifunctional aliphatic monomer and the photocurable monofunctional aliphatic monomer.

4. The composition as claimed in claim 1, wherein the photocurable monofunctional aromatic monomer and the photocurable bifunctional aromatic monomer are present in a weight ratio of 20:80 to 90:10, based on a total of 100 parts by weight of the photocurable monofunctional aromatic monomer and the photocurable bifunctional aromatic monomer.

5. The composition as claimed in claim 1, wherein:
the photocurable bifunctional aliphatic monomer is represented by Formula 1: 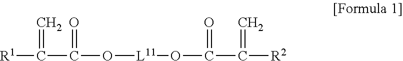
R¹ and R² are each independently hydrogen or a C₁ to C₅ alkyl group, and
L¹¹ is a substituted or unsubstituted linear or branched C₈ to C₂₀ alkylene group.

6. The composition as claimed in claim 1, wherein:
the photocurable bifunctional aromatic monomer is represented by Formula 4: 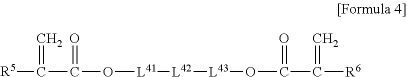
R⁵ and R⁶ are each independently hydrogen or a C₁ to C₅ alkyl group,
L⁴¹ and L⁴³ are each independently a substituted or unsubstituted C₆ to C₂₀ arylene group, and
L⁴² is a single bond or a linear or branched C₁ to C₂₀ alkylene group.

7. The composition as claimed in claim 1, wherein:
the photocurable monofunctional aliphatic monomer is represented by Formula 3: 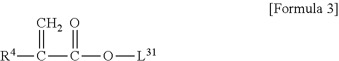
R⁴ is hydrogen or a C₁ to C₅ alkyl group, and
L³¹ is a substituted or unsubstituted linear or branched C₈ to C₂₀ alkyl group.

8. The composition as claimed in claim 1, wherein the composition includes, based on a total weight of the composition:
20 parts by weight to 60 parts by weight of the photocurable bifunctional aliphatic monomer;
5 parts by weight to 30 parts by weight of the photocurable monofunctional aromatic monomer;
10 parts by weight to 50 parts by weight of the photocurable monofunctional aliphatic monomer;
1 part by weight to 30 parts by weight of the photocurable bifunctional aromatic monomer; and
1 part by weight to 10 parts by weight of the photoinitiator.

9. A cured film for encapsulation of organic light emitting diodes, the cured film having a permittivity of 2.8 or less and a glass transition temperature of 30° C. to 120° C.

10. A cured film for encapsulation of organic light emitting diodes, the cured film having a permittivity of 2.8 or less and a glass transition temperature of 30° C. to 120° C. and including a cured product of the composition as claimed in claim 1.

11. The cured film as claimed in claim 10, wherein the photocurable bifunctional aliphatic monomer, the photocurable monofunctional aromatic monomer, the photocurable monofunctional aliphatic monomer, and the photocurable bifunctional aromatic monomer are present, in total, in an amount of 95 wt % or more in the curable component, based on a total weight of the curable component.

12. The cured film as claimed in claim 10, wherein the photocurable bifunctional aliphatic monomer and the photocurable monofunctional aliphatic monomer are present in a weight ratio of 30:70 to 70:30, based on a total of 100 parts by weight of the photocurable bifunctional aliphatic monomer and the photocurable monofunctional aliphatic monomer.

13. An organic light emitting diode display, including an organic layer including a cured product of the composition as claimed in claim 1.

14. The organic light emitting diode display in claim 13, wherein the photocurable bifunctional aliphatic monomer, the photocurable monofunctional aromatic monomer, the photocurable monofunctional aliphatic monomer, and the photocurable bifunctional aromatic monomer are present, in total, in an amount of 95 wt % or more in the curable component, based on a total weight of the curable component.

15. The organic light emitting diode display in claim 13, wherein the photocurable bifunctional aliphatic monomer and the photocurable monofunctional aliphatic monomer are present in a weight ratio of 30:70 to 70:30, based on a total of 100 parts by weight of the photocurable bifunctional aliphatic monomer and the photocurable monofunctional aliphatic monomer.

16. The organic light emitting diode display in claim 13, wherein the photocurable monofunctional aromatic monomer and the photocurable bifunctional aromatic monomer are present in a weight ratio of 20:80 to 90:10, based on a total of 100 parts by weight of the photocurable monofunctional aromatic monomer and the photocurable bifunctional aromatic monomer.

17. The organic light emitting diode display in claim 13, wherein:
the photocurable bifunctional aliphatic monomer is represented by Formula 1: 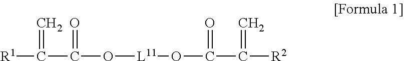
R¹ and R² are each independently hydrogen or a C₁ to C₅ alkyl group, and
L¹¹ is a substituted or unsubstituted linear or branched C₆ to C₂₀ alkylene group.

18. The organic light emitting diode display in claim 13, wherein:
the photocurable bifunctional aromatic monomer is represented by Formula 4: 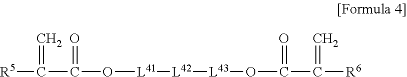
R⁵ and R⁶ are each independently hydrogen or a C₁ to C₅ alkyl group,
L⁴¹ and L⁴³ are each independently a substituted or unsubstituted C₆ to C₂₀ arylene group, and
L⁴² is a single bond or a linear or branched C₁ to C₂₀ alkylene group.

19. The organic light emitting diode display in claim 13, wherein:
the photocurable monofunctional aliphatic monomer is represented by Formula 3: 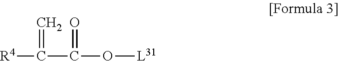
R⁴ is hydrogen or a C₁ to C₅ alkyl group, and
L³¹ is a substituted or unsubstituted linear or branched C₈ to C₂₀ alkyl group.

20. The organic light emitting diode display in claim 13, wherein the composition includes, based on a total weight of the composition:
20 parts by weight to 60 parts by weight of the photocurable bifunctional aliphatic monomer;
5 parts by weight to 30 parts by weight of the photocurable monofunctional aromatic monomer;
10 parts by weight to 50 parts by weight of the photocurable monofunctional aliphatic monomer;
1 part by weight to 30 parts by weight of the photocurable bifunctional aromatic monomer; and
1 part by weight to 10 parts by weight of the photoinitiator.
